(19) United States
(12) Patent Application Publication
(10) Pub. No.: US 2026/0243807 A1
(43) Pub. Date: Aug. 20, 2026

(54) CURRENT SENSOR

(71) Applicant: Alps Alpine Co., Ltd., Tokyo (JP)

(72) Inventors: Manabu TAMURA, Miyagi-ken (JP); Yuu KUMAGAI, Miyagi-ken (JP); Junichi HOSOGOE, Miyagi-ken (JP)

(21) Appl. No.: 19/465,571

(22) Filed: Jan. 30, 2026

Related U.S. Application Data
(63) Continuation of application No. PCT/JP2024/006260, filed on Feb. 21, 2024.

(30) Foreign Application Priority Data
Aug. 24, 2023 (JP) 2023-136639

(51) Int. Cl. G01R 19/00; G01R 15/20

(52) U.S. Cl. CPC G01R 19/0092; G01R 15/202; G01R 15/205

(57) ABSTRACT

A current sensor includes a bus bar, a magnetic sensor, a substrate, a pair of flat-plate type magnetic shields, and a case integrally formed with the bus bar and the magnetic shield, the first magnetic shield, the substrate, and the case being stacked in this order, the magnetic shield has a protrusion extending from a facing face facing the substrate and a hole in the substrate, the substrate has an engagement portion capable of engaging with the protrusion and a positioning hole, the case has a positioning boss, and in a state in which the protrusion and the engagement portion are engaged, the holes and the boss are aligned in a straight line parallel to a stacking direction, so that when fixing the magnetic shield configured as a separate part from the housing to the substrate, the magnetic shield can be easily disposed at a predetermined location on the substrate.

### CLAIM OF PRIORITY

This application is a Continuation of International Application No. PCT/JP2024/006260 filed on Feb. 21, 2024, which claims benefit of Japanese Patent Application No. 2023-136639 filed on Aug. 24, 2023. The entire contents of each application noted above are hereby incorporated by reference.

### BACKGROUND OF THE INVENTION

### 1. Field of the Invention

The present invention relates to a current sensor including a magnetic shield, the current sensor measuring the measured current flowing through a bus bar.

### 2. Description of the Related Art

In recent years, a current sensor has been used to measure the measured current flowing through devices in order to control the power supply systems of the vehicle and the like including various devices. International Application Publication No. WO2016/148032 describes a current sensor including a pair of magnetic shield plates sandwiching a conductor and a magnetoelectric conversion element, with the object of enhancing the accuracy of the current sensor while reducing the wasted space between the pair of magnetic shield plates. The pair of magnetic shields in the current sensor described in International Application Publication No. WO2016/148032 together with a sensor substrate and a bus bar is integrally formed with a resin package as a housing. However, as with this current sensor, in a configuration where the magnetic shield plate and the housing are formed as a single unit, it is difficult to achieve miniaturization, weight reduction, and cost reduction for the current sensor. Japanese Patent Application Publication No. 2018-096793 describes a current sensor in which, for the purpose of high-precision current detection, one of a pair of magnetic shields that block external magnetic fields—specifically the magnetic shield close to the magnetic detection unit including a magnetic detection element—is fixed to a circuit board by a fixing member.

The current sensor described in Japanese Patent Application Publication No. 2018-096793 is more advantageous than the current sensor described in International Application Publication No. WO2016/148032 in terms of miniaturization, weight reduction, and cost reduction because the magnetic shield installed close to the magnetic detection unit is configured as a separate component from the housing. In the current sensor described in Japanese Patent Application Publication No. 2018-096793, the relative position between the magnetic shield and the circuit board including the magnetic detection element is fixed by inserting fixing members into the fixing holes provided at the four corners of the magnetic shield. Specifically, the fixing holes of the magnetic shield are aligned with the through-holes formed in the circuit board, and the fixing members are inserted there to fix the magnetic shield to the circuit board. In this manner, the magnetic shield is positioned at the predetermined location on the circuit board using the hole position as a reference. Accordingly, the present invention provides a current sensor that can be easily positioned at a predetermined location on a substrate when fixing a magnetic shield, configured as a separate component from the housing, to the substrate provided with a magnetic detection unit.

### SUMMARY OF THE INVENTION

As a means for solving the aforementioned problem, the present invention includes the following configuration. A current sensor including a bus bar through which a measured current flows, a magnetic sensor disposed to face the bus bar to detect a magnetic field generated by the bus bar, a substrate on which the magnetic sensor is mounted, a pair of a flat-plate type first magnetic shield and a flat-plate type second magnetic shield, the pair sandwiching the bus bar, the magnetic sensor, and the substrate, and a case in which the bus bar and the second magnetic shield are provided, the first magnetic shield, the substrate, and the case being stacked in this order, wherein the first magnetic shield has a protrusion extending from a first face facing the substrate and a positioning first reference portion, wherein the substrate has an engagement portion capable of engaging with the protrusion and a positioning second reference portion, wherein the case has a positioning third reference portion, and wherein, in a state in which the protrusion and the engagement portion are engaged with each other, the first reference portion, the second reference portion, and the third reference portion are aligned in a straight line parallel to a stacking direction of the first magnetic shield, the substrate, and the case. Engaging the protrusion of the first magnetic shield with the engagement portion of the substrate facilitates alignment between the first magnetic shield and the substrate.

The first magnetic shield may include a plurality of the thin plate members stacked together, and wherein the protrusion may be a press joint where the plurality of thin plate members is crimped in a stacking direction. By using the press joint, as a protrusion, created when crimping the first magnetic shield composed of a plurality of stacked thin plate members and engaging the press joint with the engagement portion of the substrate, component processing costs and labor hours can be reduced, thereby suppressing manufacturing costs.

The first reference portion may be provided at a first thin plate member of the plurality of thin plate members included in the first magnetic shield, the first thin plate member being adjacent to the substrate. By providing the positioning first reference portion at the first thin plate member among the plurality of thin plate members constituting the first magnetic shield, it is easier to dispose the first magnetic shield at a predetermined location on the substrate, compared with providing the positioning first reference portions at all thin plate members. For example, when the shield hole penetrating the first magnetic shield is provided as the first reference portion, the length of the shield hole can be shortened by providing the shield hole only at the first thin plate member. This allows the fixing member to be easily inserted. Furthermore, since the length of the component is reduced, the strength for fixing the first magnetic shield is improved, and it is advantageous for miniaturizing and reducing the height of the current sensor.

The protrusion and the engagement portion are provided in a plurality of pairs. By providing a plurality of pairs of the protrusion and the engagement portion, and engaging each pair, positioning between the first magnetic shield and the substrate is easier, and the positioned state can be maintained.

The first reference portion may be a shield hole penetrating the first magnetic shield, wherein the second reference portion may be a substrate hole penetrating the substrate, wherein the third reference portion may be a fixing boss, wherein the fixing boss may have an anti-slip portion at a distal end of the fixing boss, and wherein in a state in which the fixing boss is inserted through the shield hole and the substrate hole, the first magnetic shield and the substrate may be fixed to the case by the anti-slip portion. With the fixing bosses inserted through the shield hole and substrate hole, by fixing the first magnetic shield and the substrate to the case with the anti-slip portion, it is possible to position the first magnetic shield, the substrate, and the case at their predetermined locations and fix them in a stacked state.

The first magnetic shield may include a plurality of the thin plate members stacked together, wherein the anti-slip portion may contact an exposed portion of a thin plate member of the plurality of thin plate members, the thin plate member being other than a second thin plate member having a greatest distance from the substrate in the stacking direction, the exposed portion having a first face facing the substrate and a second face opposite the first face, the second face being exposed.

When any thin plate member disposed between a first thin plate member adjacent to the substrate and the second thin plate member is designated as a third thin plate member, the first magnetic shield may have a hole or a cutout portion continuously formed from the second thin plate member to the third thin plate member along the stacking direction, and wherein the second face exposed from the hole or the cutout portion may be the exposed portion.

The current sensor may further include a fixing screw, wherein the first reference portion may be a shield hole penetrating the first magnetic shield, wherein the second reference portion may be a substrate hole penetrating the substrate, wherein the third reference portion may be a screw hole thread-engageable with the fixing screw, and wherein the first magnetic shield and the substrate may be fixed to the case by a screw head of the fixing screw in a state in which the fixing screw is inserted through the shield hole and the substrate hole. With the fixing screws inserted through the shield hole and substrate hole, the first magnetic shield and the substrate are fixed to the case by the screw head of the fixing screw, so that it is possible to fix the first magnetic shield, the substrate, and the case with them stacked at a predetermined location.

The first magnetic shield may include a plurality of the thin plate members stacked together, wherein the screw head may contact an exposed portion of a thin plate member of the plurality of thin plate members, the thin plate member being other than a second thin plate member having a greatest distance from the substrate in the stacking direction, the exposed portion having a first face facing the substrate and a second face opposite the first face, the second face being exposed.

When any thin plate member disposed between a first thin plate member adjacent to the substrate and the second thin plate member is designated as a third thin plate member, the first magnetic shield may have a hole or a cutout portion continuously formed from the second thin plate member to the third thin plate member along the stacking direction, and wherein the second face exposed from the hole or the cutout portion may be the exposed portion.

The first magnetic shield may include a plurality of the thin plate members stacked together, wherein a first thin plate member of the plurality of thin plate members included in the first magnetic shield, the first thin plate member being adjacent to the substrate, may have an exposed portion having a first face facing the substrate and a second face opposite the first face, the second face being exposed, and wherein the exposed portion may constitute part of a step portion or a recess portion.

With the above configuration, the length of the fixing boss or the fixing screw is shorter than when the anti-slip portion or the screw head is positioned at the second face of the second thin plate member of the first magnetic shield. This facilitates the stacking of the first magnetic shield and makes it possible to more firmly fix the first magnetic shield and the substrate to the case.

### BRIEF DESCRIPTION OF THE DRAWINGS

FIG. 1 is a perspective view schematically showing the appearance of the current sensor according to the first embodiment;

FIG. 2 is a schematic cross-sectional view showing the configuration of the main part of the current sensor taken along line II-II in FIG. 1;

FIG. 3 is a schematic cross-sectional view showing the configuration of a modification of the current sensor shown in FIG. 2;

FIG. 4 is a plan view of the current sensor shown in FIG. 3;

FIGS. 5A and 5B are explanatory diagrams of the structure of a magnetic shield with a stacked structure in the related art;

FIGS. 6A and 6B are explanatory diagrams of the structure of the magnetic shield with a stacked structure in the current sensor of the present invention;

FIG. 7 is a schematic cross-sectional view showing the configuration of another modification of the current sensor shown in FIG. 2;

FIG. 8 is a schematic cross-sectional view showing the configuration of another modification of the current sensor shown in FIG. 2;

FIG. 9 is a schematic plan view showing the configuration of the current sensor in FIG. 8;

FIG. 10 is a schematic cross-sectional view showing the configuration of the current sensor according to the second embodiment;

FIG. 11 is a schematic plan view showing the configuration of the current sensor according to the second embodiment;

FIG. 12 is a schematic cross-sectional view showing the configuration of a modification of the current sensor shown in FIG. 10;

FIG. 13 is a schematic plan view showing the configuration of the current sensor in FIG. 12;

FIG. 14 is a schematic cross-sectional view showing the configuration of a current sensor in the related art; and

FIG. 15 is a schematic cross-sectional view showing the configuration of a current sensor without a cover.

### DESCRIPTION OF THE PREFERRED EMBODIMENTS

### First Embodiment

The following describes embodiments of the present invention with reference to the accompanying drawings. The same part numbers are assigned to identical components in each drawing, and explanations are omitted as appropriate. To indicate the positional relationship between respective components, the reference coordinates are shown in each drawing as appropriate. In the reference coordinates, the direction in the width dimension of the bus bar is defined as the X direction (third direction), the direction of the extension of the bus bar, the direction being perpendicular to the X direction, is defined as the Y direction (second direction), and the stacking direction in which the bus bar and the magnetic sensor are stacked, the direction being perpendicular to both the X direction and the Y direction is defined as the Z direction (first direction). The X direction is the direction of the sensitivity axis of the magnetic sensor, and the Y direction and Z direction are perpendicular to the sensitivity axis.

FIG. 14 is a schematic cross-sectional view showing the configuration of a current sensor 100 in the related art. The current sensor 100 shown in the figure includes a pair of parallel plate-type magnetic shields 104A and 104B that sandwiches a bus bar 101 through which the measured current flows and a magnetic sensor 102 provided on a substrate 103. The magnetic shield 104A is insert molded into a cover 106, and the magnetic shield 104B is insert molded into a case 105. Thus, in a configuration including the case 105 and the cover 106, with the magnetic shields 104B and 104A insert-molded into the case 105 and the cover 106, respectively, it is difficult to miniaturize and thin the current sensor 100, and it is disadvantageous in terms of cost reduction. Therefore, the following describes an aspect of implementing the present invention as a current sensor that does not include the cover 106 holding the magnetic shield 104A, the current sensor offering advantages in terms of miniaturization, thinness, and low cost.

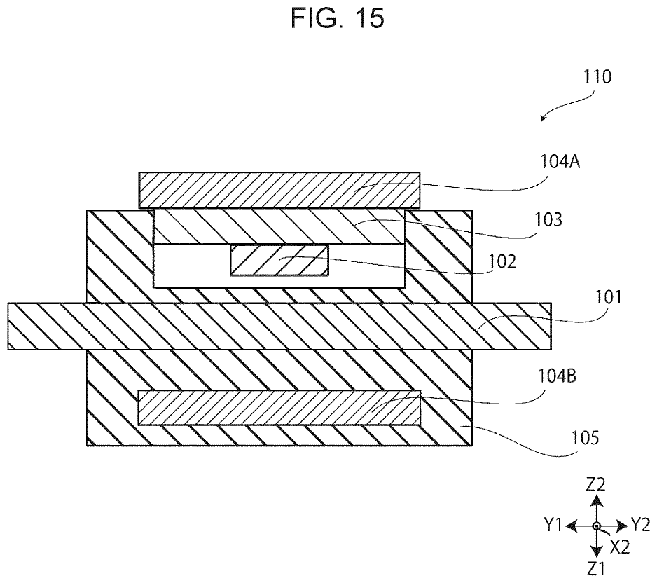

FIG. 15 is a schematic cross-sectional view showing the configuration of a current sensor 110 without a cover. Since the current sensor 110 shown in the figure does not include a cover, the magnetic shield 104A of the pair of the magnetic shields 104A and 104B is directly provided on the substrate 103. Thus, when directly mounting the magnetic shield 104A on the substrate 103, the magnetic shield being provided close to the magnetic sensor 102 relative to the bus bar 101, it is difficult to position the magnetic shield 104A at a predetermined location on the substrate 103. Therefore, the current sensor of the present invention has a configuration for stably, easily, and accurately determining the position of the magnetic shield 104A relative to the substrate 103. Embodiments of the current sensor of the present invention will be described below.

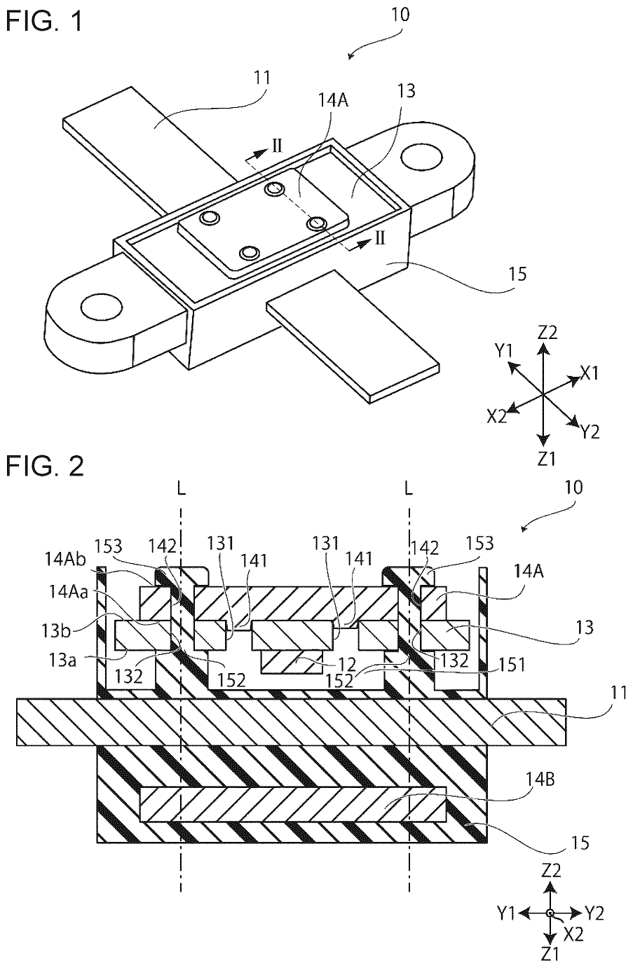

FIG. 1 is a perspective view schematically showing the appearance of the current sensor 10 according to the present embodiment. FIG. 2 is a schematic cross-sectional view showing the configuration of the main part of the current sensor 10 taken along line II-II in FIG. 1. The current sensor 10 includes a bus bar 11, a magnetic sensor 12, a substrate 13, a pair of a flat-plate type magnetic shield 14A (first magnetic shield) and a flat-plate type magnetic shield 14B (second magnetic shield), and a case 15. The magnetic shield 14A, the substrate 13, the magnetic sensor 12, the bus bar 11, and the magnetic shield 14B are stacked in this order from the Z2 to Z1 direction, with the bus bar 11 and the magnetic shield 14B being provided within the case 15.

The bus bar 11 is a conductor formed into a plate shape through which the measured current flows, and is made of a material such as copper, brass, or aluminum. The magnetic sensor 12 detects the magnetic field generated by the bus bar 11 when the measured current flows, and is mounted on a Z1-side face 13a of the substrate 13, the face 13a facing the bus bar 11 in the Z direction. The detection face of the magnetic sensor 12 faces the bus bar 11, and the sensitivity axis is oriented parallel to the detection face. The induced magnetic field generated when the measured current flows through the bus bar 11 near the detection face of the magnetic sensor 12 includes a large amount of components in the X direction. Therefore, by positioning the magnetic sensor 12 so that the sensitivity axis is parallel to the X direction, the magnetic field generated by the bus bar 11 can be detected with high accuracy.

A magnetoresistive element, a Hall element, or the like can be used as a detection element of the magnetic sensor 12. Note that the above configuration shows an example where the magnetoresistive element is used as the detection element of the magnetic sensor 12. When using another detection element, the orientation of the detection face is required to be appropriately adjusted and positioned.

The magnetic shields 14A and 14B are disposed to sandwich the bus bar 11, the magnetic sensor 12, and the substrate 13 in the Z direction, and are composed of metal plate-like bodies or the like. The magnetic shields 14A and 14B suppress magnetic noise affecting the magnetic sensor 12, thereby improving the measurement accuracy of the current sensor 10.

The case 15 may be integrally formed with the bus bar 11 and the magnetic shield 14B, for example, by insert molding. Alternatively, the bus bar 11 may be inserted into the case 15 after the magnetic shield 14B has been integrally molded into the case 15 by insert molding.

The magnetic shield 14A includes a protrusion 141 protruding from a facing face 14Aa (first face), the facing face 14Aa facing the substrate 13. Additionally, as the first reference portion, the magnetic shield 14A has a hole 142 (shield hole) penetrating in the Z direction, and through which a fixing boss 152 described later is allowed to be inserted.

The substrate 13 includes an engagement portion 131 capable of engaging with the protrusion 141 at a Z2-side facing face 13b facing the magnetic shield 14A, the facing face 13b being opposite the face 13a on which the magnetic sensor 12 is mounted. The engagement portion 131 is only required to be capable of engaging with the protrusion 141, so that, instead of a hole penetrating in the Z direction, for example, the engagement portion 131 may be formed as a recess that does not penetrate in the Z direction, corresponding to the shape of the protrusion 141.

Engaging the protrusion 141 of the magnetic shield 14A with the engagement portion 131 of the substrate 13 facilitates determining the relative positional relationship between the magnetic shield 14A and the substrate 13. Specifically, by fitting the protrusion 141 into the engagement portion 131, the magnetic shield 14A and the substrate 13 can be easily aligned.

To ensure reliable and easy alignment, as shown in FIG. 2, it is preferable that the current sensor 10 include a plurality of pairs of the protrusion 141 and the engagement portion 131. By providing a plurality of pairs of the protrusion 141 and the engagement portion 131 and engaging respective pairs, positioning between the magnetic shield 14A and the substrate 13 is easier, and the aligned state can be reliably maintained.

As a positioning second reference portion, the substrate 13 has a hole 132 that penetrates in the Z direction and through which the fixing boss 152 described later can be inserted. By engaging the protrusion 141 with the engagement portion 131, the magnetic shield 14A is positioned at a predetermined location on the substrate 13, causing the hole 142 of the magnetic shield 14A to align with the hole 132 (substrate hole) of the substrate 13. Specifically, when viewed in the Z direction, the hole 142 of the magnetic shield 14A and the hole 132 of the substrate 13 can be aligned to form a continuous hole.

The case 15, made of resin and other materials, is integrally formed with the insert-molded bus bar 11 and the insert-molded magnetic shield 14B. The case 15 has a storage recess 151 facing the substrate 13. Furthermore, the fixing boss 152 protruding in the Z2 direction as a positioning third reference portion is provided inside the storage recess 151.

Engaging the protrusion 141 with the engagement portion 131 causes the hole 142 to align with the hole 132 when viewed in the Z direction. Therefore, the fixing boss 152 as the third reference portion can be easily inserted into the hole 142 and the hole 132. Inserting the fixing boss 152 defines the positional relationship between the magnetic shield 14A, the substrate 13, and the case 15. In this state, the hole 142, the hole 132, and the fixing boss 152 are disposed along a straight line L parallel to the stacking direction (Z direction) of the magnetic shield 14A, the substrate 13, and the case 15.

In a state in which the fixing boss 152 is inserted through the hole 142 and the hole 132, the magnetic shield 14A and the substrate 13 are fixed to the case 15 by an anti-slip portion 153 provided at the Z2-side end (distal end) of the fixing boss 152. The anti-slip portion 153 is formed by, for example, heat crimping the Z2-side end (distal end) of the fixing boss 152 after inserting the fixing boss 152 through the hole 142 and the hole 132.

The anti-slip portion 153 has an outer dimension, when viewed in the Z direction, that is larger than the respective inner diameters of the hole 142 and the hole 132. Furthermore, the anti-slip portion 153 closely contacts a Z2-side face 14Ab of the magnetic shield 14A. Therefore, the anti-slip portion 153 functions as a holding member that holds the magnetic shield 14A and the substrate 13 at a predetermined location within the case 15.

The positional relationship between the magnetic shield 14A, the substrate 13, and the case 15 is fixed by the anti-slip portion 153 with the magnetic sensor 12 on the substrate 13 positioned at a position facing the bus bar 11 within the storage recess 151.

As described above, in the current sensor 10, the relative positions of the magnetic shield 14A, the substrate 13, and the case 15 can be determined with the magnetic shield 14A, the substrate 13, the bus bar 11, and the magnetic shield 14B being disposed in a stacked configuration in this order in the direction from Z2 to Z1 direction. By fixing the substrate 13 and the magnetic shield 14A in their predetermined locations with the case 15 as a reference, it is possible to prevent misalignment of the positions of the bus bar 11, the magnetic shield 14A, and the magnetic shield 14B relative to the magnetic sensor 12 provided on the substrate 13. Therefore, the current sensor 10, with excellent measurement accuracy, in which an error due to positional misalignment is suppressed is provided.

### Modification

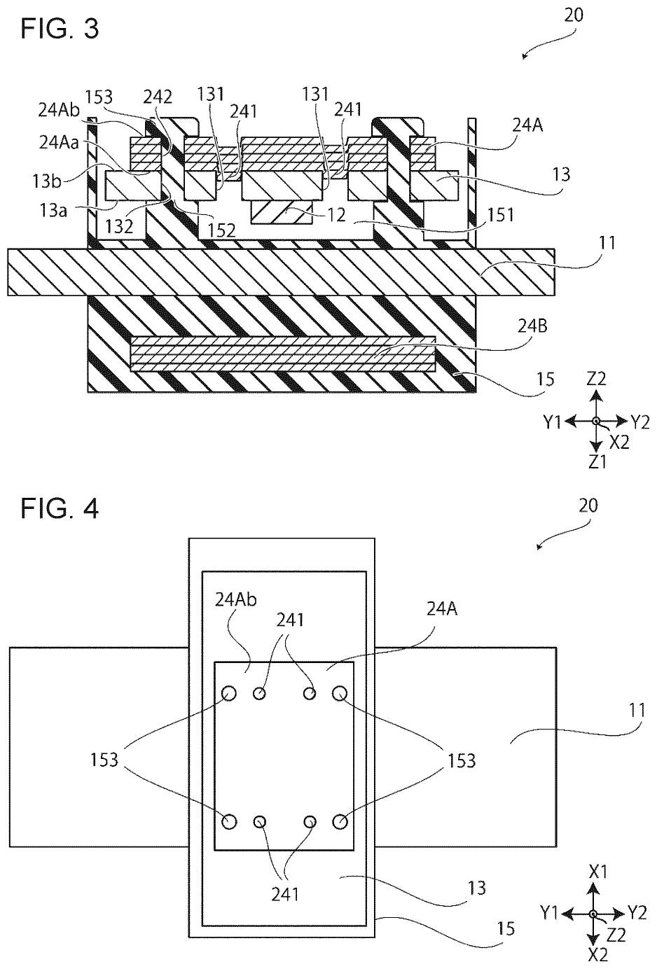

FIG. 3 and FIG. 4 are a cross-sectional view and a plan view, respectively, schematically showing the configuration of a current sensor 20, which is a modification of the current sensor 10 in FIG. 2. The current sensor 20 shown in these figures differs from the current sensor 10 in FIG. 2 in that the current sensor 20 includes magnetic shields 24A and 24B each composed of a plurality of metal plate-like bodies with an identical shape stacked together, instead of the magnetic shields 14A and 14B each composed of a single metal plate-like body.

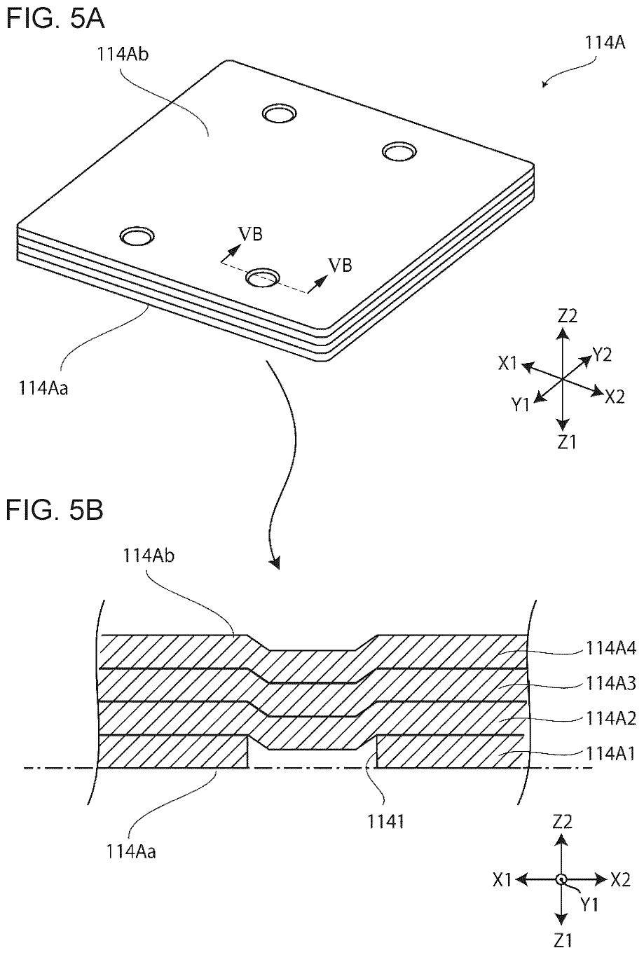

Before describing the magnetic shield 24A of the current sensor 20, the structure of a magnetic shield 114A with a typical stacked structure in the related art will be described. FIGS. 5A and 5B are explanatory diagrams of the structure of the magnetic shield 114A having a stacked structure in the related art. As shown in FIG. 5A, the magnetic shield 114A has a structure where a plurality of metal plates is stacked and crimped by punching from the upper side (Z2-side). FIG. 5B shows the cross-sectional structure of the portion taken along line VB-VB in FIG. 5A.

Simply stacking a plurality of metal plates and crimping them together by punching produces a shape like the protrusion 141 of the magnetic shield 14A shown in the first embodiment. When there is variation in the protrusion amount or shape of such portions, a problem that the portions become tilted even when the portions are disposed on a flat face may occur.

In the magnetic shield 114A with a stacked structure in the related art, as shown in FIG. 5B, a hole 1141 is provided in a metal plate 114A1 disposed at the bottom (Z1-side). When viewed in the Z direction, the portion overlapping the hole 1141 is punched from an upper face 114Ab, crimping metal plates 114A1 to 114A4. At this point, the protrusion of the metal plate 114A2 adjacent to the metal plate 114A1 is pressed into the hole 1141. This prevents the formation of the protrusion protruding from a lower facing face 114Aa of the magnetic shield 114A, as indicated by the single-dot line.

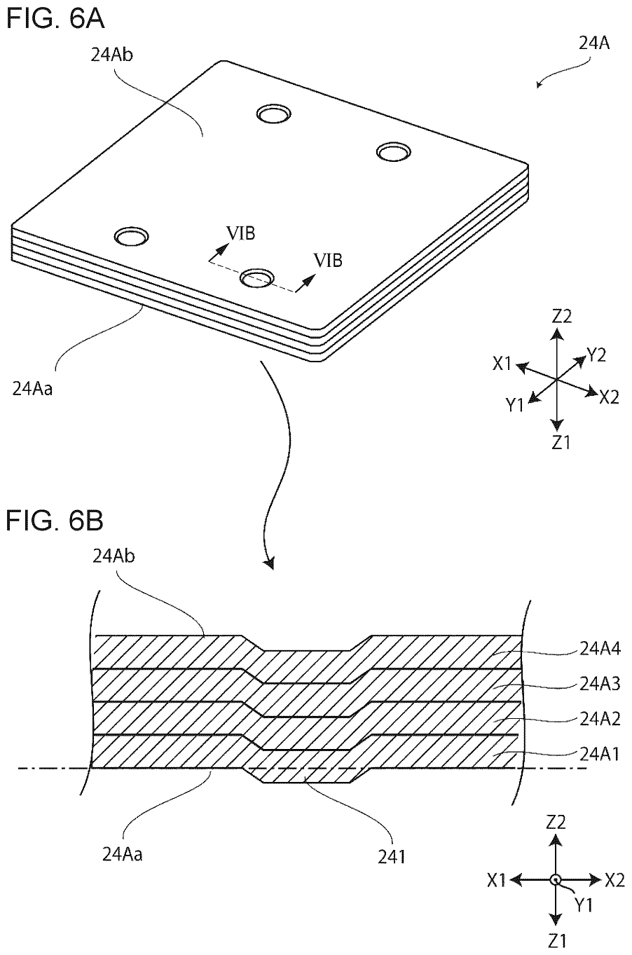

FIGS. 6A and 6B are explanatory diagrams of the structure of the magnetic shield 24A that has the stacked structure of the current sensor 20. As shown in FIG. 6A, the magnetic shield 24A is identical to the magnetic shield 114A in the related art of FIGS. 5A and 5B in that the magnetic shield 24A is formed by stacking a plurality of metal plates and crimping them by punching from the upper side (Z2-side).

However, in the magnetic shield 24A, as shown in the cross-sectional view of FIG. 6B, a metal plate 24A1 positioned at the bottom does not have a hole at the crimped portion marked with line VIB-VIB in FIG. 6A. Therefore, for all metal plates 24A1 to 24A4, a recess is formed at an upper face 24Ab of the crimped portion, and a protrusion is formed at a facing face 24Aa facing the lower substrate 13. Therefore, a press joint 241, which protrudes from the lower facing face 24Aa indicated by the single-dot line and is formed when crimping with a punch, is used for aligning the magnetic shield 24A with the substrate 13. Specifically, the press joint 241, of the magnetic shield 24A, which is crimped in the stacking direction, is utilized as a protrusion for engaging with the engagement portion 131 of the substrate 13.

As described above, in the magnetic shield 24A, a portion of the press joint 241, which is necessary for processing, is used as a protrusion that is caused to protrude from the facing face 24Aa facing the substrate 13 of the magnetic shield 24B, and engage with engagement portion 131 of the substrate 13. In this manner, utilizing the press joint 241 as a protrusion facilitates alignment between the magnetic shield 24A and the substrate 13, and it is possible to reduce component processing costs and labor hours, thereby suppressing the manufacturing cost of the magnetic shield 24A. Moreover, the magnetic shield 24B may have a structure with a protrusion at one face, as in the magnetic shield 24A, or may have a structure without a protrusion, as the magnetic shield 114A in the related art.

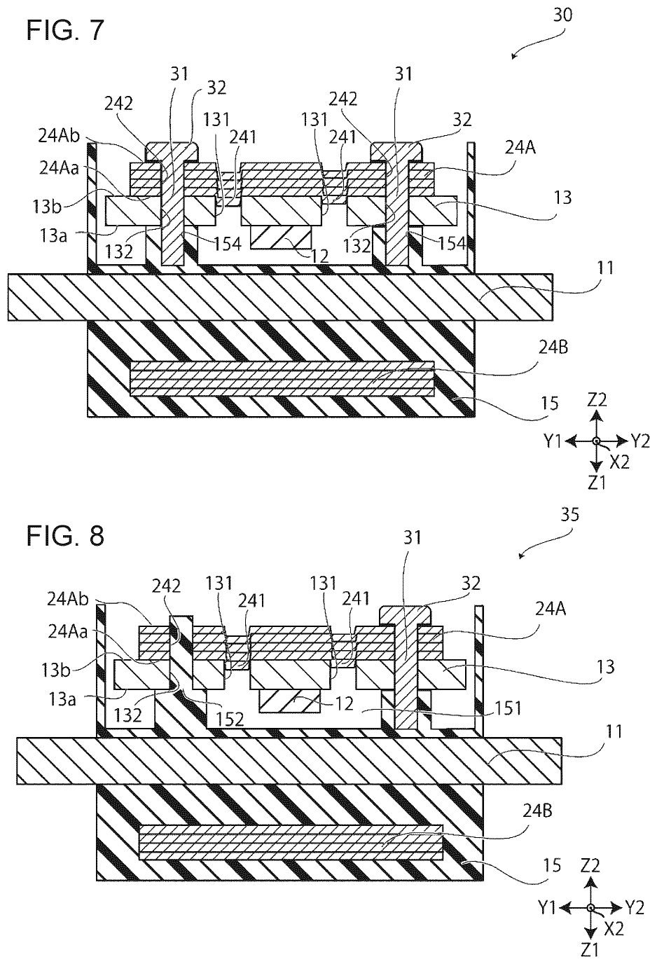

FIG. 7 is a schematic cross-sectional view of the current sensor 30 as another modification of the current sensor 20 in FIG. 3. The current sensor 30 differs from the current sensor 10 in that the current sensor 30 includes a fixing screw 31, and the case 15 has a screw hole 154, as the third reference portion, capable of thread-engaging with the fixing screw 31. Furthermore, when viewed in the Z direction, the inner diameters of a hole 242 (first shield hole) and the hole 132 are larger than the threaded portion of the fixing screw 31 and smaller than the outer diameter of the screw head 32.

In the current sensor 30, the magnetic shield 24A and the substrate 13 are fixed to the case 15 by the screw head 32 of the fixing screw 31, with the fixing screw 31 inserted through the hole 242 and the hole 132. This allows the magnetic shield 24A, the substrate 13, and the case 15 to be fixed in a stacked state at a predetermined location, with the fixing screw 31 serving as a holding member.

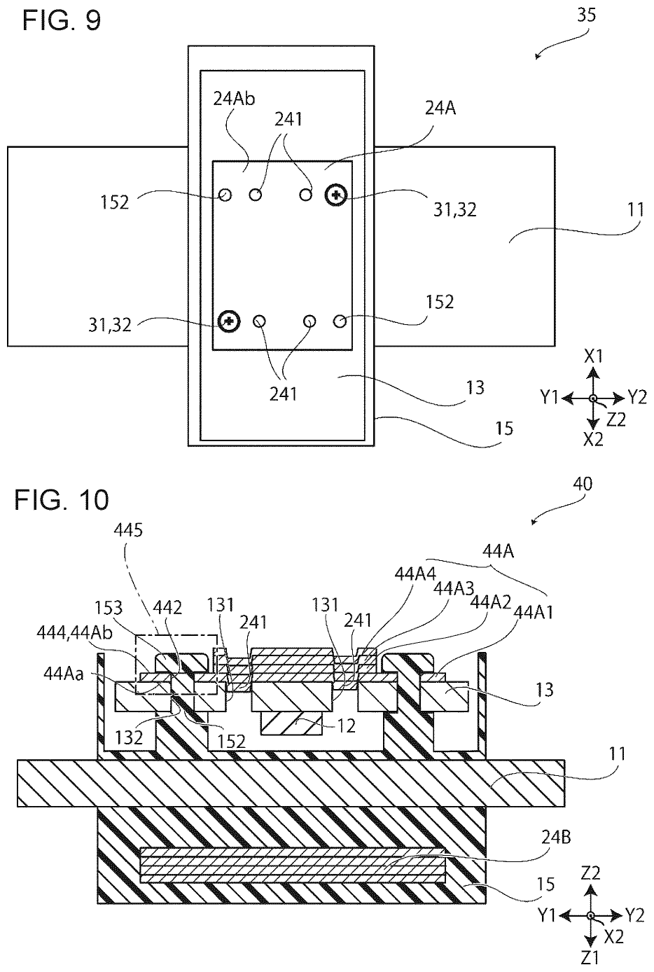

FIG. 8 and FIG. 9 are a cross-sectional view and a plan view, respectively, schematically showing the appearance of current sensor 35 as another modification of the current sensor 20 in FIG. 3. As shown in these figures, the current sensor 35 differs from the current sensor 20 in that the magnetic shield 24A, the substrate 13, and the case 15 are fixed, using two fixing bosses 152 and two fixing screws 31.

As in the current sensor 35, a different fixing means may be used in order to fix the magnetic shield 24A, the substrate 13, and the case 15. The different fixing means may be disposed in combinations and configurations different from that shown in FIG. 9. For example, one fixing boss 152 may be combined with three fixing screws 31, or three fixing bosses 152 may be combined with one fixing screw 31. Alternatively, the configuration may include the anti-slip portion 153 provided at the distal ends of all or some of the fixing bosses 152. FIG. 9 shows an example where the magnetic shield 24A has four fixing means, but the number of fixing means is not limited to four, but may be, for example, two, three, or five or more.

### Second Embodiment

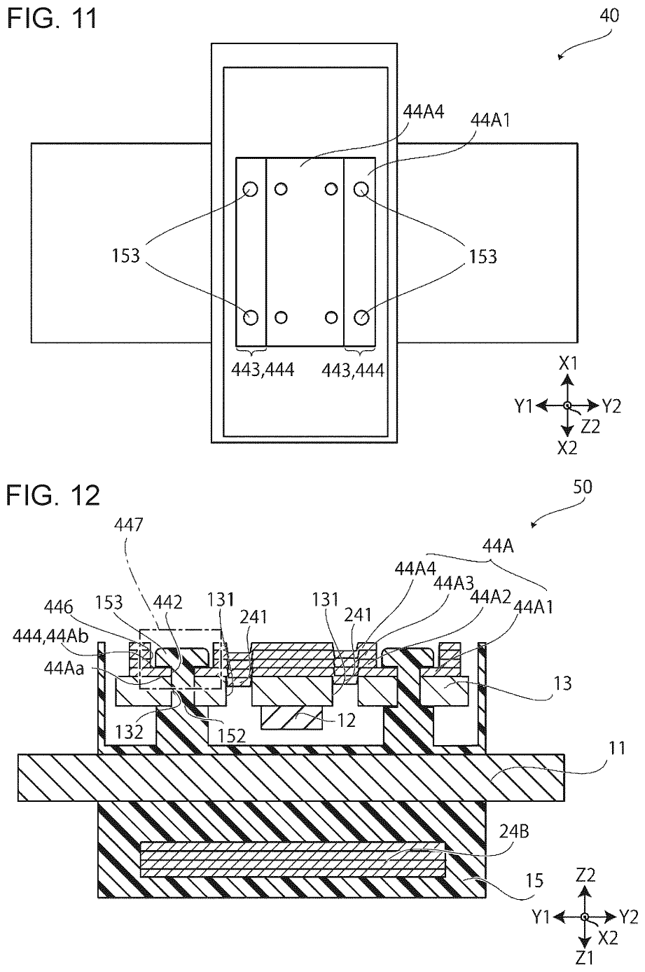

FIG. 10 and FIG. 11 are a cross-sectional view and a plan view, respectively, schematically showing the configuration of a current sensor 40 of the present embodiment. As shown in FIG. 10 and FIG. 11, the current sensor 40 differs from the current sensor 20 in FIG. 3 in that the current sensor 40 includes a magnetic shield 44A instead of the magnetic shield 24A.

The magnetic shield 44A has a hole 442, as the first reference portion, which is provided only in a thin plate member 44A1 (first thin plate member) adjacent to the substrate 13, among the plurality of thin plate members 44A1, 44A2, 44A3, and 44A4 of the magnetic shield 44A.

In other words, when a plurality of thin plate members 44A1, 44A2, 44A3, and 44A4 is viewed from the Z2-side, the thin plate member 44A1 has an exposed portion 444 that protrudes beyond the thin plate members 44A2, 44A3, and 44A4, and has the hole 442 in the exposed portion 444. Furthermore, when the Z2-side is considered the upper side, the exposed portion 444 is positioned below (the Z1-side) the upper face of the thin plate member 44A4, forming a step portion 445.

By forming the hole 442 in the exposed portion 444 of the thin plate member 44A1, the anti-slip portion 153 can be disposed at the step portion 445. This allows the protrusion of the anti-slip portion 153 relative to the upper face of the thin plate member 44A4 to be reduced, compared with the case where the anti-slip portion 153 is disposed at the upper face of the thin plate member 44A4. That is, miniaturization and reduced height in the Z direction can be achieved.

Furthermore, forming the hole 442 in the exposed portion 444 of the thin plate member 44A1 reduces the depth of the hole 442 in the stacking direction. This makes it easier to fit the fixing boss 152 into the hole 442. Additionally, the length of the fixing boss 152 in the Z direction is shorter, thereby improving the strength of the fixing boss 152. Therefore, by fitting the fixing boss 152 of the case 15 into the hole 442 of the magnetic shield 44A and the hole 132 of the substrate 13, and then fixing the magnetic shield 44A and the substrate 13, the magnetic shield 44A and the substrate 13 can be fixed more firmly to the case 15.

The magnetic shield 44A shown in FIG. 10 has a cutout portion 443 continuously formed from the thin plate member 44A4 (second thin plate member) with the greatest distance from the substrate 13 in the stacking direction (Z direction) to the thin plate member 44A2 (third thin plate member) adjacent to the thin plate member 44A1 among the thin plate members 44A1 to 44A4. Specifically, the thin plate members 44A2 to 44A4 other than the thin plate member 44A1 have the cutout portion 443, and, when viewed from the face 44Ab (second face) of the magnetic shield 44A, the exposed portion 444, which is exposed, of the thin plate member 44A1 has the holes 442.

As described above, the magnetic shield 44A has the hole or the cutout portion 443 continuously formed from the thin plate member 44A4 to the thin plate member 44A2 along the stacking direction (Z direction) among the thin plate members 44A2 and 44A3 (third thin plate member) disposed between the thin plate member 44A1 (first thin plate member) and the thin plate member 44A4 (second thin plate member). When viewed from the Z2 toward Z1 direction, the face 44Ab exposed from the cutout portion 443 is the exposed portion 444.

In the magnetic shield 44A, only thin plate member 44A1, serving as the first thin plate member, has the hole 442 as the first reference portion, and the step portion 445 is formed by the exposed portion 444 of the thin plate member 44A1 and the Y direction end faces of the thin plate members 44A2 to 44A4. Specifically, a portion of the step portion 445 is formed by the exposed portion 444.

As shown in FIG. 11, when viewed in the Z direction, the anti-slip portion 153 contacts the exposed portion 444 that is exposed, and the anti-slip portion 153 holds the magnetic shield 44A and the substrate 13 with the exposed portion 444 serving as a holding face. In this manner, the magnetic shield 44A can be fixed in the predetermined location within the case 15.

In the current sensor 40 shown in FIGS. 10 and 11, when viewed in the stacking direction of the magnetic shield 44A, the thin plate member 44A1 in contact with the substrate 13 is formed larger than the other thin plate members 44A2 to 44A4. And, the hole 442 (shield hole) as the first reference portion is formed in the exposed portion 444 of the thin plate member 44A1, which protrudes beyond the other thin plate members 44A2 to 44A4.

In FIG. 10, thin plate members 44A2 to 44A4 have the same shape and size, and each is formed with a shape different from that of the thin plate member 44A1. However, this is not limited to this configuration. For example, thin plate member 44A2 may be formed with the same shape and size as thin plate member 44A1, while thin plate members 44A3 to 44A4 may be formed with shapes different from thin plate member 44A1. At this time, when viewed from the Z2 to Z1 direction, a portion protruding beyond the thin plate members 44A3 to 44A4 at the Z2-side face of the thin plate member 44A2 may be the exposed portion 444, and the hole 442 may penetrate the thin plate members 44A2 and 44A1.

That is, when a plurality of the thin plate members continuously stacked (large plate members) including thin plate member 44A1 is formed with the identical shape and size, and includes a portion protruding beyond the remaining thin plate members (small plate members) including the thin plate member 44A4, the thin plate members may have the exposed portion 444 at the Z2-side face of the large plate member farthest from the substrate 13, and the exposed portion 444 may have the hole 442 penetrating all the large plate members.

According to this configuration, when viewed in the stacking direction, any of the thin plate members 44A1 to 44A3 among the thin plate members 44A1 to 44A4 is exposed. Specifically, a thin plate member, other than the thin plate member 44A4 that has the greatest distance from the substrate 13 in the stacking direction, has the exposed portion 444 exposed at the face 44Ab opposite a facing face 44Aa facing the substrate 13. The magnetic shield 44A, the substrate 13, and the case 15 are fixed when the anti-slip portion 153 contacts the exposed portion 444.

Furthermore, the hole 442 is short, compared with the case in which the thin plate member 44A4 has the exposed portion 444. Therefore, the fixing boss 152 can be easily fitted into the hole 442. Additionally, the fixing boss 152 is shorter, and the strength of the current sensor 40 is improved.

Note that FIGS. 10 and 11 show an aspect in which fixing is performed using the anti-slip portion 153, but the screw head 32 may be used instead of part or all of the anti-slip portion 153. When using the fixing screw 31 instead of the fixing boss 152, by providing the hole 442 in one or a plurality of the thin plate members 44A1 to 44A3 other than thin plate member 44A4, the length of the hole 442 in the Z direction is shorter, so that it is possible to reduce the load of the operation of fixing the magnetic shield 44A and the substrate 13 to the case 15 and improve the fixing strength.

Furthermore, in FIG. 10 and FIG. 11, the cutout portion 443 is formed across the entire length of both ends in the Y direction, but may be formed only around the first reference portion (hole 442). Reducing the cutout area can suppress degradation of shielding performance.

### Modification

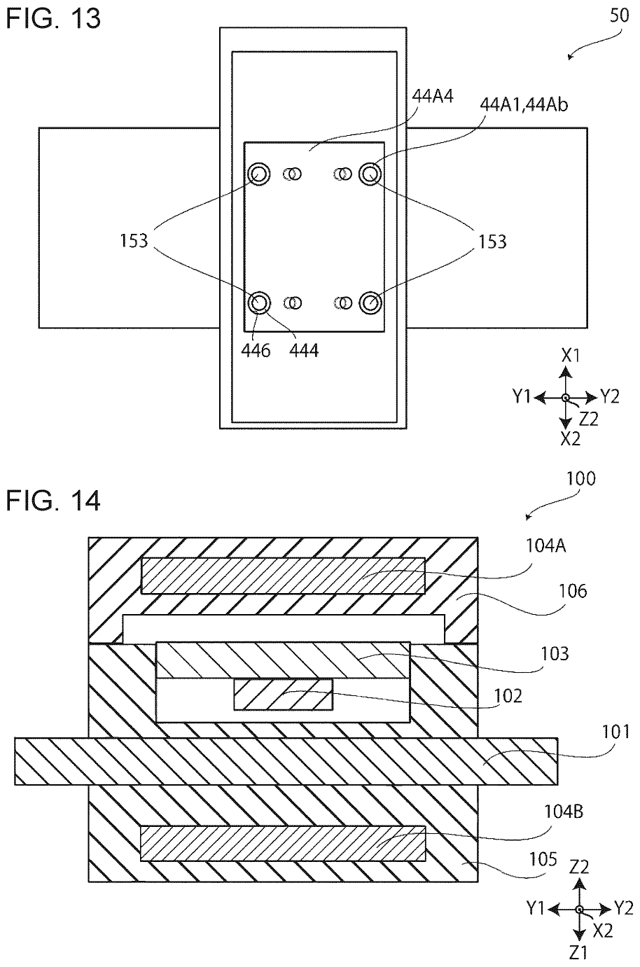

FIG. 12 and FIG. 13 are a cross-sectional view and a plan view, respectively, schematically showing the configuration of a current sensor 50 as a modification of the current sensor 40 in FIG. 10. The magnetic shield 44A of the current sensor 50 shown in these figures differs from that of the current sensor 40 in that the thin plate members 44A2 to 44A4 have a hole 446 instead of the cutout portion 443. When viewed from the Z2 direction toward the Z1 direction, the current sensor 50 has a recess portion 447 defined by the exposed portion 444 of the thin plate member 44A1, the exposed portion 444 being exposed from the hole 446, and the end faces of the thin plate members 44A2 to 44A4 in the Y direction.

The magnetic shield 44A of the current sensor 50 has the hole 446 continuously formed from the thin plate member 44A4 to the thin plate member 44A2 along the stacking direction. The magnetic shield 44A and the substrate 13 are fixed to the case 15 by the anti-slip portion 153 contacting the exposed portion 444 of the thin plate member 44A4, the exposed portion 444 protruding from the hole 446.

As in the case where the thin plate members 44A2 to 44A4 have the cutout portion 443, when the thin plate members 44A2 to 44A4 have the hole 446, the Z2-side face of the large plate member farthest from the substrate 13 may have the exposed portion 444, and the exposed portion 444 may have the hole 442 penetrating all large plate members. This configuration results in a shorter length of the hole 442 in the stacking direction formed in the exposed portion 444, compared with the case in which the thin plate member 44A4 has the exposed portion 444. Therefore, the fixing boss 152 can be easily fitted into the hole 442, enhancing the strength of the current sensor 50.

### Industrial Applicability

The present invention is useful as a current sensor for measuring the measured current flowing through devices, for example, in order to control the power supply system of vehicles and the like including various devices.

1. A current sensor comprising:
a bus bar through which a current to be measured flows;
a substrate;
a magnetic sensor disposed on the substrate to face the bus bar to detect a magnetic field generated by the current flowing through the bus bar;
a pair of flat-plate type magnetic shields including a first magnetic shield and a second magnetic shield; and
a case in which the bus bar and the second magnetic shield are provided,
wherein the first magnetic shield, the substrate, and the case are stacked in this order along a first direction, such that the bus bar, the magnetic sensor, and the substrate are sandwiched between the first magnetic shield and the second magnetic shield,
wherein the first magnetic shield has at least one protrusion extending from a first face facing the substrate and a first reference portion for positioning,
wherein the substrate has at least one engagement portion capable of engaging with the protrusion and a second reference portion for positioning,
wherein the case has a third reference portion for positioning,
and wherein in a state in which the protrusion and the engagement portion are engaged with each other, the first reference portion, the second reference portion, and the third reference portion are aligned in a straight line parallel to the first direction.

2. The current sensor according to claim 1,
wherein the first magnetic shield includes a plurality of thin plate members stacked together in the first direction,
and wherein the protrusion is a press joint where the plurality of thin plate members are crimped in the first direction.

3. The current sensor according to claim 2, wherein a first thin plate member among the plurality of thin plate members which is adjacent to the substrate has the first reference portion.

4. The current sensor according to claim 1, wherein the at least one protrusion includes a plurality of protrusions, and the at least engagement portion includes a plurality of engagement portions so as to form a plurality of pairs with corresponding protrusions.

5. The current sensor according to claim 1,
wherein the first reference portion is a shield hole penetrating the first magnetic shield, the second reference portion is a substrate hole penetrating the substrate, and the third reference portion is a fixing boss having an anti-slip portion at a distal end of the fixing boss,
and wherein when the fixing boss is inserted through the shield hole and the substrate hole, the first magnetic shield and the substrate are fixed to the case by the anti-slip portion.

6. The current sensor according to claim 5,
wherein the first magnetic shield includes a plurality of thin plate members stacked together in the first direction, including a second thin plate member which is farthest from the substrate,
and wherein the anti-slip portion contacts an exposed portion of one of the plurality of thin plate members other than the second thin plate member, the exposed portion being a part of a second face of the first magnetic shield opposite the first face.

7. The current sensor according to claim 6,
wherein the plurality of thin plate members include a first thin plate member adjacent to the substrate, the second thin plate member farthest from the substrate, and at least one third thin plate member disposed between the first thin plate member and the second thin plate member, the first magnetic shield has a hole or a cutout portion continuously formed from the second thin plate member to the third thin plate member along the first direction, and the second face exposed from the hole or the cutout portion is the exposed portion.

8. The current sensor according to claim 1, further comprising a fixing screw,
wherein the first reference portion is a shield hole penetrating the first magnetic shield, the second reference portion is a substrate hole penetrating the substrate, and the third reference portion is a screw hole thread-engageable with the fixing screw,
and wherein in a state in which the fixing screw is inserted through the shield hole and the substrate hole, the first magnetic shield and the substrate are fixed to the case by a screw head of the fixing screw.

9. The current sensor according to claim 8, wherein
the first magnetic shield includes a plurality of thin plate members stacked together in the first direction, including a second thin plate which is farthest from the substrate,
and wherein the screw head contacts an exposed portion of one of the plurality of thin plate members other than the second thin plate member, the exposed portion being a part of a second face of the first magnetic shield opposite the first face.

10. The current sensor according to claim 9,
wherein the plurality of thin plate members include a first thin plate member adjacent to the substrate, the second thin plate member farthest from the substrate, and at least one third thin plate member disposed between the first thin plate member and the second thin plate member, the first magnetic shield has a hole or a cutout portion continuously formed from the second thin plate member to the third thin plate member along the first direction, and the second face exposed from the hole or the cutout portion is the exposed portion.

11. The current sensor according to claim 7,
wherein the first thin plate member has an exposed portion which is a part of the second face of the first magnetic shield opposite the first face,
and wherein the exposed portion constitutes part of a step portion or a recess portion.
